(19) United States
(12) Patent Application Publication
(10) Pub. No.: US 2016/0380651 A1
(43) Pub. Date: Dec. 29, 2016

(54) MULTIPLE ECC CHECKING MECHANISM WITH MULTI-BIT HARD AND SOFT ERROR CORRECTION CAPABILITY

(71) Applicant: Samsung Electronics Co., Ltd., Suwon-si (KR)

(72) Inventor: John H. HUGHES, JR., Morgan Hill, CA (US)

(21) Appl. No.: 14/751,126

(22) Filed: Jun. 25, 2015

(51) Int. Cl. H03M 13/29; G06F 11/10

(52) U.S. Cl. CPC H03M 13/2906; G06F 11/1076

(57) ABSTRACT

Embodiments of the inventive concept include a system and method for correcting multi-bit errors. A data vector and corresponding check vector can be stored. Error correcting circuitry can be used to identify which bits in the data vector, if any, are in error. Using information from a fault information storage, a correction vector can also be applied to the data vector to generate an alternate data vector. Error correcting circuitry can be used to identify which bits in the alternate data vector, if any, are in error. A final data vector can then be generated based on the data vector, the alternate data vector, and the results of the error correcting circuitries, which can then be returned as the read data vector.

### FIELD

The invention pertains to error correction, and more particularly to error correcting codes that can handle both soft and hard errors in the same data.

### BACKGROUND

Error correction of Random Access Memory (RAM) soft errors can be performed using a single-error correcting/double-error detecting (SEC/DED) Hamming code. Soft errors (SEUs) are the result of high energy particles causing a random bit to change value. The SEC/DED correction method depends on the fact that SEUs have a very low rate of occurrence and rarely cause more than one bit error in a single RAM word. In addition, RAM design places physically proximate RAM cells in different RAM words, which further reduces the likelihood of multiple soft errors in a single RAM word.

A second cause of RAM errors are manufacturing faults. These faults can manifest as hard faults (Stuck-At) that cause a RAM bit to always read as a 0 (SA-0) or 1 (SA-1), which are considered classical faults. There are also failures due to parametric, leakage, or bridging faults. Such faults are considered non-classical because they do not present a persistent (“hard”) presence, but can be data or operating point dependent. For purposes of this analysis, only hard faults are considered correctable.

A SEC/DED error correcting code can correct a single SEU bit flip in a fault-free RAM location protected by a SEC/DED error correcting code. A SEC/DED error correcting code can also correct a single manufacturing stuck bit. But the coincidence of a SEU and a Stuck-At fault in the same RAM word could result in a two bit error which is not correctable with a SEC/DEC code and would cause a data integrity loss.

A need remains for a way to use error correcting codes that that can identify and correct multi bit errors.

### BRIEF DESCRIPTION OF THE DRAWINGS

FIG. 1 shows a circuit that can use error correcting codes to correct multi-bit errors, according to an embodiment of the inventive concept.

FIG. 2 shows details of the correction vector circuitry of FIG. 1.

FIG. 3 shows details of the correction vector generation circuitry of FIG. 2.

FIG. 4 shows the application of the correction vector of FIG. 3 to a data vector.

FIG. 5 shows a chart of different possible cases based on the results of the error correcting circuitries of FIG. 1.

FIG. 6 shows a computer system that can include the circuit of FIG. 1 to correct for multi-bit errors.

FIGS. 7A-7B show a flowchart of a procedure to use error correcting codes to correct multi-bit errors in data, according to an embodiment of the inventive concept.

FIG. 8 shows a flowchart of different ways to correct the data vector based on the results of the error correcting circuitries.

### DETAILED DESCRIPTION

A small number of manufacturing faults in embedded (Random Access Memory) RAM can be tolerated if the existence of the fault is known to the error correcting code (ECC) mechanism. The RAM fault information used in this enhanced correction method is a list of the locations with a single Stuck-At fault and the bit position that has the fault, called the hard fault table. The polarity of the bit fault (Stuck-At-0 or Stuck-At-1) is not required. The fault location information (word and bit) can be used as the data is read from RAM, so a direct-mapped structure such as a Read-Only Memory (ROM) or a content-addressable memory (CAM) can be used. The information is used to generate a correction vector which is the same width as the RAM data word and is all zeros when a fault-free location is accessed, and has a single one, in the bit position with the fault, for locations with a hard fault. The correction vector can be exclusive-ORed (XOR) with the RAM read data to create an alternate data value where the bit with the hard fault has the opposite state from its Stuck-At value.

The ECC mechanism uses two single-error correcting/double-error detecting (SEC/DED) ECC checkers that can operate in parallel. The primary ECC checker (ECC1) receives the RAM data, which is comprised of data and check bits. A second ECC checker (ECC2) receives the alternate copy of the RAM data after the application of the correction vector. The results from the two ECC checks are then compared using a set of rules, which indicate what the correct data should be for output.

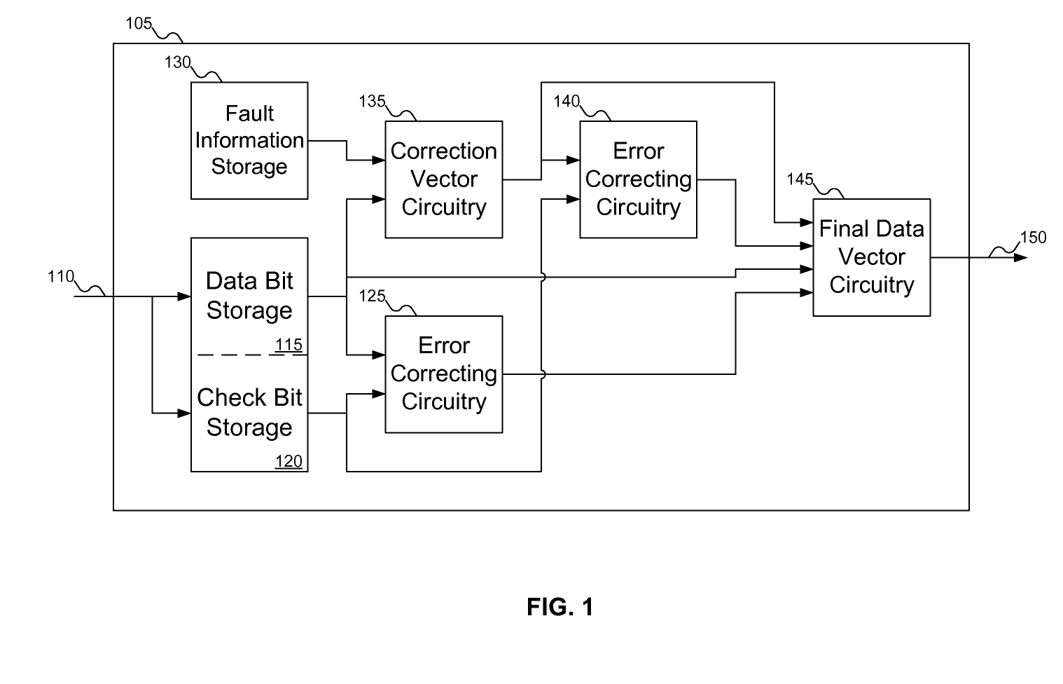

FIG. 1 shows a circuit that can use error correcting codes to correct multi-bit errors, according to an embodiment of the inventive concept. In FIG. 1, circuit 105 can be incorporated in a memory module, such as in RAM. But circuit 105 can be incorporated into any module that includes data storage, such as caches on a processor.

A data vector (that is, a set of data bits, which can also be called a data word) can be input via line 110. The data vector can be stored in data bit storage 115. Circuit 105 does not show control inputs, such as a line for indicating whether data is to be read or written. In addition, circuit 105 can be generalized to any desired memory configuration, including data that can be read or written in parallel, among other possibilities.

A check vector (that is, a set of check bits) can also be input via line 110, and can be stored in check bit storage 120. The check vector can be generated using any desired ECC algorithm, such as an SEC/DED Hamming code. In FIG. 1, the check vector can be generated before the data vector into data bit storage 115, but it is also possible for the check vector to be generated using ECC circuitry within circuit 105 before the data vector is stored in data bit storage 115.

While FIG. 1 shows data bit storage 115 as distinct from check bit storage 120, the check bits can be stored intermixed with the data bits, within a single storage element. All that matters is that the check bits can be processed as check bits, rather than as data bits. Similarly, while the above description might be read as suggesting that the data vector and the check vector are input at different times, the data vector and the check vector can be input at the time.

When the data vector is read from data bit storage 115, the check vector can also be read from check bit storage 120. These vectors can be input into error correcting circuitry 125 (referred to above as ECC1), which can determine if the check vector is consistent with the data vector. One way in which ECC1 125 can operate is to use the check vector to correct any errors in data vector, as would normally happen in using the ECC code. Another way in which ECC1 125 can operate is to recalculate the check vector from the data vector as read from data bit storage 115 and compare the result with the check vector as read from check bit storage 120. Regardless of the manner in which ECC1 125 operates, the result is an indication of whether the number of bits in error (between the data vector and the check vector) is zero, one, or more than one (a multi-bit error).

Circuit 105 also includes fault information storage 130, sometimes called a hard fault table, which stores information about the bits in data bit storage 115 that have Stuck-At faults. As noted above, fault information storage 130 indicates whether a bit is Stuck or not; fault information storage 130 does not need to store whether the bits are Stuck at 0 or 1. But a person of ordinary skill in the art will recognize that fault information storage 130 could include additional information, such as whether the bit is Stuck at 0 or 1, without affecting the operation of embodiments of the inventive concept.

Fault information storage 130, since it can store information about bits that were defective at the time of manufacture of the storage, can be pre-computed: either at the time of manufacture or sometime thereafter. Fault information storage 130 can be a direct-mapped structure such as Read-Only Memory (ROM) or content-addressable memory (CAM) can be used, among other possibilities. Fault information storage 130 can also be writeable storage, in case additional bits become stuck after manufacture.

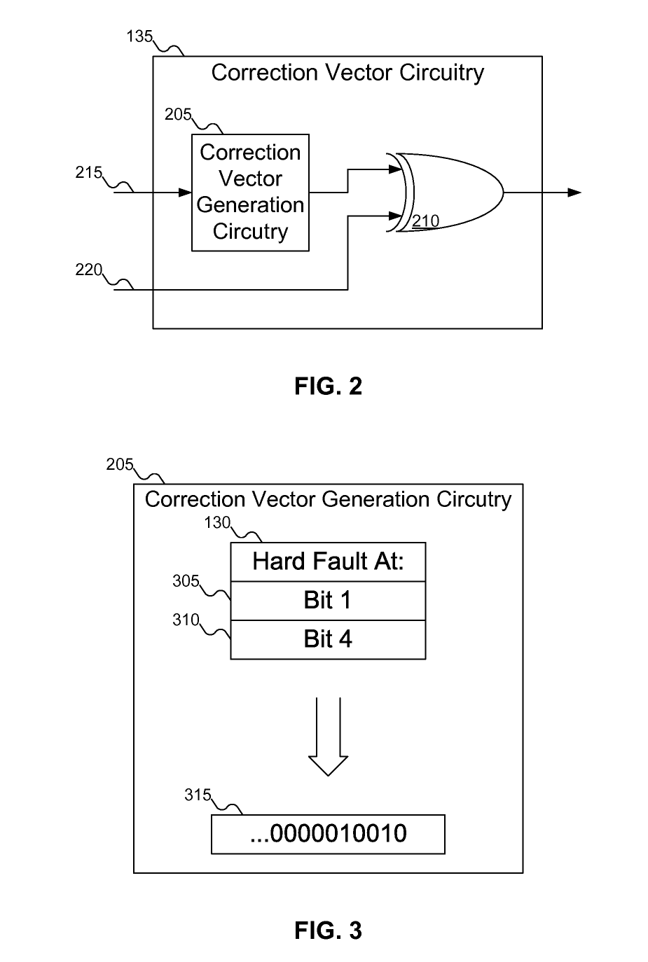

The information from fault information storage 130 can be fed into correction vector circuitry 135. Correction vector circuitry 135 can also receive a copy of the data vector from data bit storage 115. Correction vector circuitry 135 can then use the information from fault information storage 130 to produce an alternate data vector. Effectively, alternate data vector can be the original data vector, but with the values of the bits flipped where fault information storage 130 indicates a bit is stuck. Correction vector circuitry 135 is discussed further with reference to FIGS. 2-4 below.

In addition to ECC1 125, circuit 105 can include ECC2 140. ECC2 140 is functionally the same as ECC1 125, except that ECC2 140 operates on the alternate data vector, rather than the data vector read from data bit storage 115. In effect, ECC2 140 assumes that every Stuck bit in the data vector was actually intended to have the other binary value, and checks to see if the check vector is consistent with that alternate data vector.

The results of ECC1 125 and ECC2 140, along with the original and alternate data vectors, can then be input into final data vector circuitry 145. Final data vector circuitry can then determine if the data vector, as read from data bit storage 115, requires correction; if correction is required, whether the data vector can be corrected; and, if the data vector can be corrected, how to correct it. As a result, the output of circuitry 105 can be the desired data vector, as originally written to data bit storage 115 (despite potential hard or soft errors, if they can be corrected).

Final data vector circuitry 145 can use various rules to determine what to output as the final data vector. These rules can include the following:

1) If both ECC1 125 and ECC2 140 indicate no error, then the original data vector has no errors and can be output without correction. This situation can arise when there are no errors (either Stuck-At bits or soft errors), or when any Stuck-At bits match the data (that is, the value stored for the bit is the same as the value to which that bit is stuck).

2) If ECC1 125 indicates a single bit error (SBE) at bit A, and ECC2 140 indicates no error, then there was a single bit error due to the known Stuck-At fault, and the alternate data vector can be output without correction.

3) If ECC1 125 and ECC2 140 both indicate SBEs in the same bit position, then the error is a soft error (SEU) and the original data vector can be used after correction using the check vector.

4) If ECC1 125 indicates a multi-bit error (MBE) and ECC2 140 indicates a SBE, then the bit identified by ECC2 140 was a SEU, and the other bit identified by ECC1 125 was a Stuck-At error. The alternate data vector can be used after correction using the check vector.

5) If ECC1 125 and ECC2 140 both indicate a MBE then there was a multiple bit SEU, which cannot be corrected.

6) If ECC1 125 indicates a SBE, and ECC2 140 indicates a MBE then a multi-bit SEU and a Stuck-At occurred, which cannot be corrected.

These rules can be grouped into four categories:

1) No error observed: either there are no errors in the data vector or any Stuck-At bits match the values written to those bits.

2) A SBE (either a SEU or a Stuck-At bit that does not match the value written to the bit): the error can be corrected using the error correcting code. Note that a SEU would have occurred on a bit that is not identified as a Stuck-At bit in fault information table 130.

3) Both a SEU and a Stuck-At bit: the Stuck-At bit can be corrected using fault information table 130 and the SEU can be corrected using the error correcting code and the check vector.

4) Any other MBE: error correction cannot be performed.

Yet another way to look at embodiments of the invention is to assign a code to ECC1 125 and ECC2 140. The code can include the letters: Z, meaning zero errors; S, meaning a single-bit correctable error; and M, meaning a multi-bit error that the ECC cannot correct by itself. Note that M indicates that the individual circuit, either ECC1 125 or ECC2 130 cannot, by itself, correct the multi-bit error; M does not mean that the error in the data vector is uncorrectable by circuit 105.

Using this code for ECC1 125 and ECC2 140, the results of both error correcting circuits can be generated as the concatenation of the two individual codes. The possible results can be represented as the set {ZZ, ZS, SZ, SS, MS, MM, SM}. (Note that ZM and MZ are not possible cases: if one ECC indicates a multi-bit error, it is not possible for the other ECC to indicate no errors at all.) The choices for error correction are: Use ECC1 125 checker action, use ECC2 140 checker action, or indicate a multi-bit error. The correct action can be determined by a simple precedence sequence:

1) If fault information storage 130 indicates that there is no Stuck-At bit cell in the data vector, then ECC1 125 and ECC2 140 results should be identical and the result of ECC1 125 result can be used.

2) Otherwise, if ECC2 140 indicates a MBE, correct the MBE using ECC2 140. Otherwise, use the result of either ECC1 125 or ECC2 140, depending on which indicates the better result, where Z is better than S, and S is better than M.

Embodiments of the inventive concept provide a tradeoff. Instead of discarding storage modules that have hard faults, these modules can now be used. The tradeoff is that the module's storage capacity is reduced by the capacity of fault information storage 130, and the module requires added space for the logic of circuit 105.

Although the embodiment of the invention described above can handle one Stuck-At bit (hard fault), other embodiments of the invention can support more than one Stuck-At bit. The number of error correcting circuits required to handle n hard faults is 2′. Thus, 2 ECCs are required to handle one hard fault, 4 ECCs are required to handle 2 hard faults, and so on.

Turning to FIG. 2, FIG. 2 shows details of the correction vector circuitry of FIG. 1. In FIG. 2, correction vector circuitry 135 is shown as including correction vector generation circuitry 205 and XOR gate 210. Correction vector generation circuitry 205, as the name implies, can generate a correction vector that can be applied to a data vector. Correction vector generation circuitry 205 can receive information from fault information storage 130 of FIG. 1 via line 215 to generate the correction vector. The correction vector can then be XORed with the data vector, which can be received via line 220, to generate the alternate data vector.

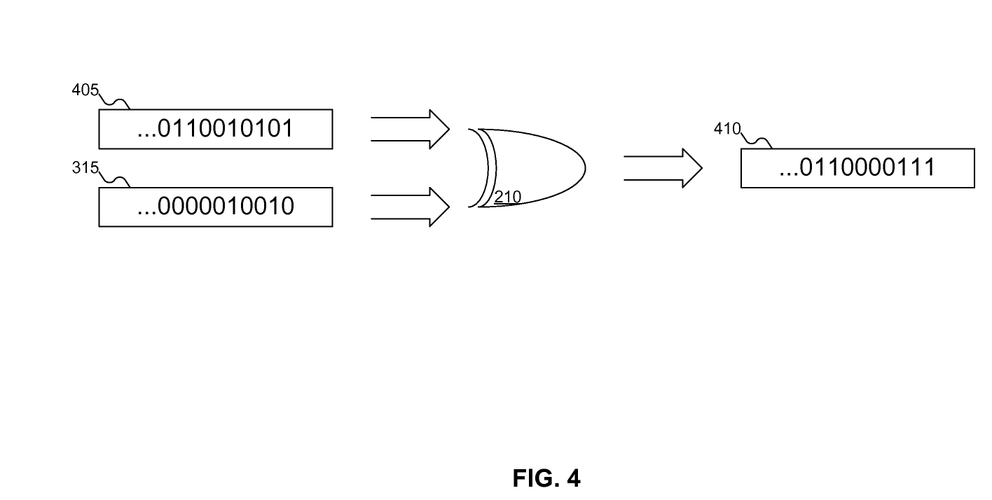

FIG. 3 shows details of the correction vector generation circuitry of FIG. 2 in another embodiment of the inventive concept. In FIG. 3, fault information storage 130 is stored within correction vector generation circuitry 205, rather than externally to correction vector generation circuitry 205 (as shown in FIG. 1). In FIG. 3, fault information storage 130 is shown as indicating that two bits 305 and 310, specifically bits 1 and 4, have Stuck-At faults. From this, correction vector 315 can be generated. Correction vector 315 can include 1 bits at the positions indicated as being Stuck. As can be seen (with bit 0 as the least significant bit at the right of correction vector 315), the only bits in correction vector 315 that are set to 1 are bits 1 and 4: all other bits are set to 0 . This correction vector can then be XORed with the data vector to change the value of the bits in the data vector that are Stuck, resulting in the alternate data vector.

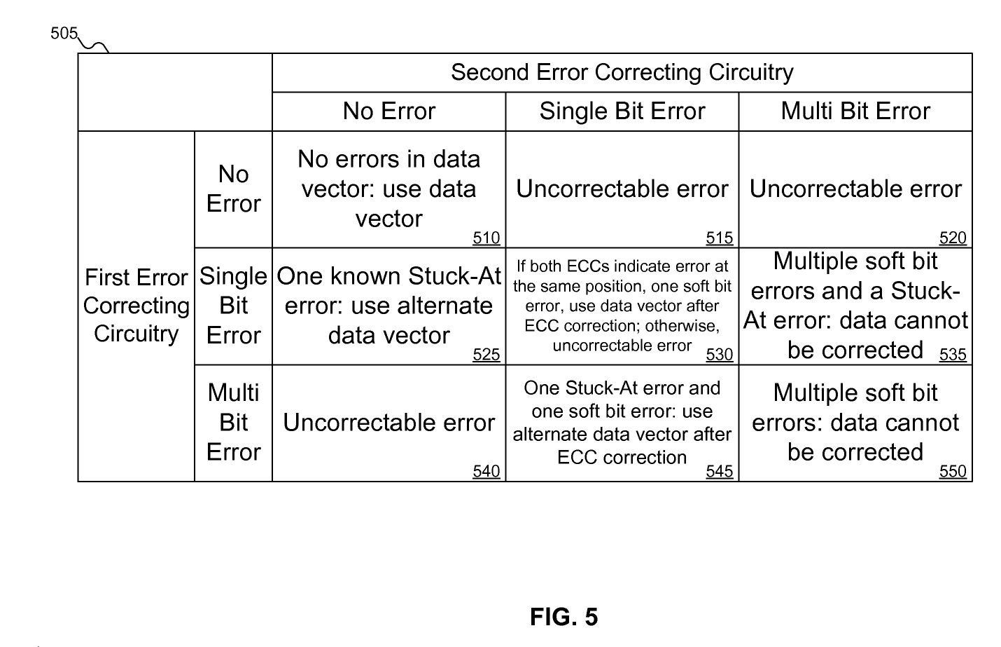

FIG. 4 shows the application of the correction vector of FIG. 3 to a data vector. In FIG. 4, data vector 405 is XORed with correction vector 315 using XOR gate 210. As can be seen in alternate data vector 410, the value of bits 1 and 4 in data vector 405 have been flipped in alternate data vector 410.

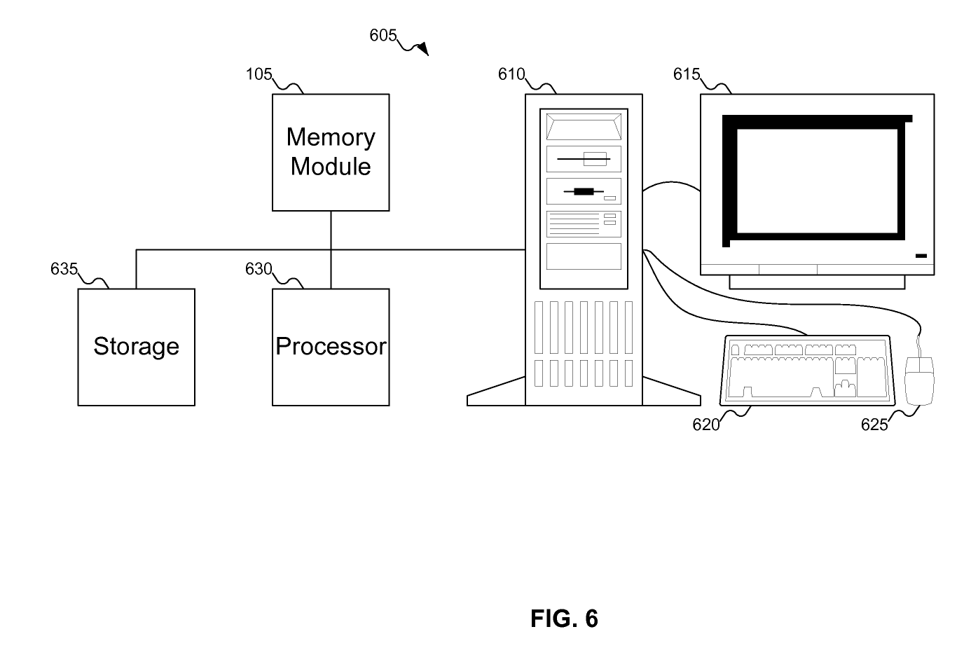

FIG. 5 shows a chart of different possible cases based on the results of the error correcting circuitries of FIG. 1. In FIG. 5, table 505 shows the possible cases for how to correct the data vector read from data bit storage 115, if the data vector requires correction and can be corrected. Because table 505 only considers two ECCs, table 505 corresponds to an embodiment of the inventive concept as shown in FIG. 1. But as noted above, more than two errors can be handled by increasing the number of ECCs, with a corresponding increase in the number of dimensions to table 505.

Returning to the embodiment of the inventive concept shown in FIG. 5, there are three possible results generated by error correcting circuitry 125 of FIG. 1: no error, a single bit error, or a multi-bit error. Similarly, there are three possible results generated by error correcting circuitry 140: no error, a single bit error, or a multi-bit error. Therefore, there are nine possible results.

If neither ECC1 125 nor ECC2 140 indicates an error, then the data vector does not require correction, as indicated in cell 510. If ECC1 125 indicates no error, but ECC2 140 indicates either a single bit or multi-bit error, then there is an uncorrectable error in the data vector, as indicated in cells 515 and 520. Note that cell 520 corresponds to the case coded ZM, which is not a possible combination.

If ECC1 125 indicates a single bit error but ECC2 140 indicates no error, then there was a single bit that was Stuck at the wrong value (that is, the bit was Stuck at 0 when the value written was 1, or the bit was Stuck at 1 when the value written was 0). Since the alternate data vector had no errors, the alternate data value should be used in place of the data vector, as indicated in cell 525.

If ECC1 125 and ECC2 140 both indicate a single bit error, there are two possible cases. Either both ECCs indicate a single bit error at the bit, or they indicate single bit errors at different bits. If both ECCs indicate a single bit error at the same bit, then that bit was subject to a soft error, and the data vector can be used after correcting the soft error using an ECC (either ECC1 125 or ECC2 140 can be used). If ECC1 125 and ECC2 140 indicate different single bit errors, then the error is uncorrectable. Both these cases are indicated in cell 530.

If ECC1 125 indicates a single bit error and ECC2 140 indicates a multi-bit error, then the data vector includes both a Stuck-At error and multiple soft errors. This combination of errors cannot be corrected, as indicated in cell 535.

If ECC1 125 indicates a multi-bit error and ECC2 140 indicates no error, there is an uncorrectable error, as indicated in cell 540. Note that cell 540 corresponds to the cases coded MZ, which is not a possible combination. If ECC1 125 indicates a multi-bit error and ECC2 140 indicates a single bit error, then the data vector has both one soft error and one Stuck-At error. By using the alternate data vector and correcting it using ECC2, the correct data can be determined and output from circuit 105, as indicated in cell 545. Finally, if both ECC1 125 and ECC2 140 indicate multi-bit errors, then there are multiple soft errors, which cannot be corrected using circuit 105, as indicated in cell 550.

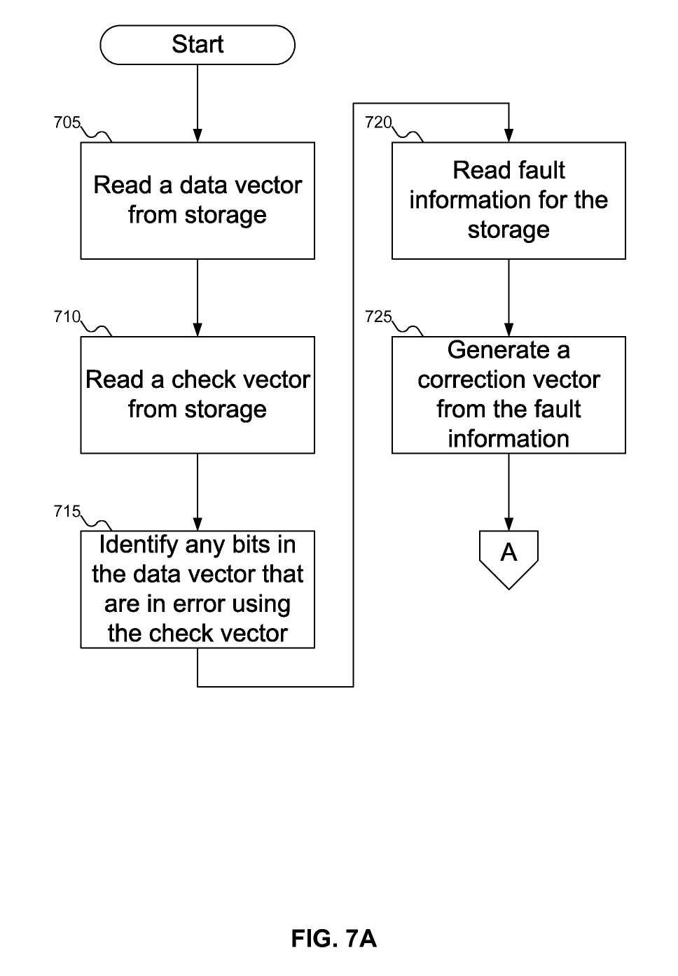

FIG. 6 shows a computer system that can include the circuit of FIG. 1, as part of a memory module, to correct for multi-bit errors. In FIG. 6, computer system 605 is shown as including computer 610, monitor 615, keyboard 620, and mouse 625. A person skilled in the art will recognize that other components can be included with computer system 605: for example, other input/output devices, such as a printer. In addition, computer system 605 can include conventional internal components, such as central processing unit 630 or storage 635. Although not shown in FIG. 6, a person skilled in the art will recognize that computer system 605 can interact with other computer systems, either directly or over a network (not shown) of any type. Finally, although FIG. 6 shows computer system 605 as a conventional desktop computer, a person skilled in the art will recognize that computer system 605 can be any type of machine or computing device capable of providing the services attributed herein to computer system 605, including, for example, a laptop computer, a tablet computer, a personal digital assistant (PDA), or a smart phone, among other possibilities.

Where embodiments of the inventive concept are implemented in a memory module, such as memory module 105, memory module 105 can be included in computer system 405. But embodiments of the inventive concept can be implemented in other types of modules, which could also be included in computer system 405 or other applicable machines.

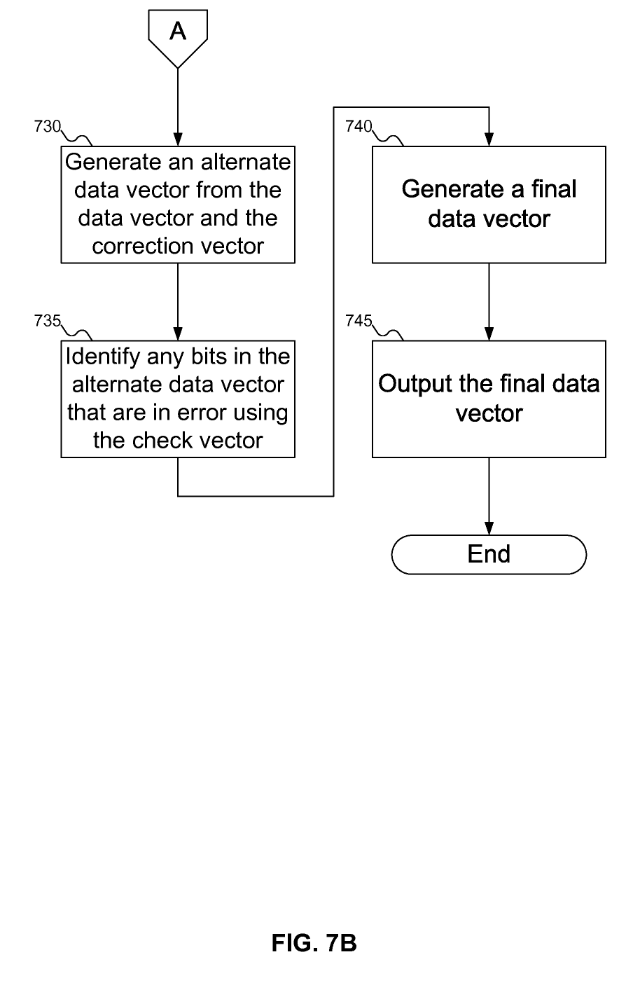

FIGS. 7A-7B show a flowchart of a procedure to use error correcting codes to correct multi-bit errors in data, according to an embodiment of the inventive concept. In FIG. 7A, at block 705, a data vector is read from data bit storage 115. At block 710, a check vector is read from check bit storage 120. At block 715, error correcting circuitry 125 can identify if there are any bits in the data vector that are in error (relative to the check vector). At block 720, the information from fault information storage 130 can be read, to identify any known hard errors in data bit storage 115. At block 725, correction vector circuitry 135 can generate a correction vector from the information read from fault information storage 130.

At block 730 (FIG. 7B), correction vector circuitry 135 can generate an alternate data vector from the data vector (as read from data bit storage 115) and the correction vector. At block 735, error correcting circuitry 140 can identify if there are any bits in the alternate data vector that are in error (relative to the check vector). At block 740, final data vector circuitry 145 can generate the final data vector using the data vector, the alternate data vector, and the results of error correcting circuitries 125 and 140. As described above, the final vector can be the original data vector, the alternate data vector, the original data vector after error correction, or the alternate data vector after error correction, depending on what errors were identified by error correcting circuitries 125 and 140. Finally, at block 745, the final data vector can be output from circuit 105.

In FIGS. 7A-7B (and in the other flowcharts below), one embodiment of the inventive concept is shown. But a person skilled in the art will recognize that other embodiments of the inventive concept are also possible, by changing the order of the blocks, by omitting blocks, or by including links not shown in the drawings. All such variations of the flowcharts are considered to be embodiments of the inventive concept, whether expressly described or not.

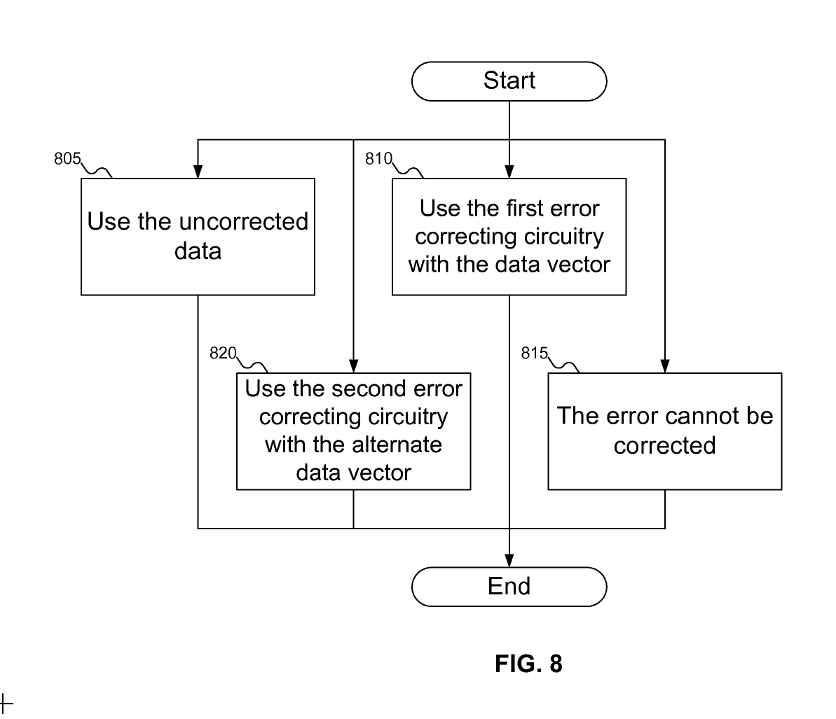

FIG. 8 shows a flowchart of different ways to correct the data vector based on the results of the error correcting circuitries. In FIG. 8, at block 805, final data vector circuitry 145 can output the data vector without correction. Alternatively, at block 810, final data vector circuitry 145 can output the data vector with error correction (that is, correcting for an error identified by error correcting circuitry 125). Alternatively, at block 905, final data vector circuitry 145 can output the alternate data vector without correction. Alternatively, at block 815, final data vector circuitry 145 can output the alternate data vector with error correction (that is, correcting for an error identified by error correcting circuitry 140). As described above, which approach used by final data vector circuitry 145 depends on what errors, if any, are identified by error correcting circuitries 125 and 140.

Embodiments of the inventive concept can include advantages over other approaches to error correction:

1) Structural redundancy is commonly used in large RAM structures where the overhead of the redundancy has a lower impact. Structural redundancy replaces a whole segment of the RAM with a spare segment if there are any faulty cells in the original segment of the RAM. Structural redundancy has the ability to eliminate a large number of manufacturing faults, both classical and non-classical. But structural redundancy has the weakness that a single manufacturing fault in the redundant structure makes it unusable. The redundant structure is mapped using non-volatile fuses at test time, so externally the RAM appears identical to a RAM without the redundancy feature. In contrast, embodiments of the inventive concept can account for errors without having to allocate large sections of RAM to a redundant structure.

2) Error correcting codes with greater correcting capacity have been considered, both academically and by manufacturers. The Hamming code is limited to SEC/DED, but there are other coding techniques that can correct two or more bits. While correcting two or more bits in data has been used in forward error correction (FEC) of data streams where the latency and complexity of check bit generation and error correction are not typically an issue. But latency and complexity of error correcting codes that can correct for two more bits in block-oriented applications like RAM make such codes less appealing for a number of reasons.

Error correcting codes are commonly classified using a three number identifier (n, k, t), but often just written as (n, k), where n is the number of bits in the coded word, k is the number of those bits that are available for data, and t is the number of bits in the code word that the code is able to correct. (The difference of n and k (n−k) is therefore the number of check bits in the code word.)

For a correcting code to be functional it must identify the faulty bit(s) with maximum code efficiency. An n-bit word needs a log₂(n)-bit pointer for each bit that needs to be corrected. Therefore, a first approximation of code word size to correction capacity is given by: (n−k)˜t*log₂(n). Using the SEC/DED Hamming code as an example, a 32-bit word needs 5 check bits, and a 64-bit word needs 6 check bits. In actuality, the SEC/DED Hamming code requires 6 check bits for a 32-bit word and 7 check bits for a 64-bit word, so this approximation is close. The reason the approximation is lower than the actual number of required check bits is due to the assumption that the Hamming code is 100% efficient, which it is not.

But as the number of correctable bits increases, the size of the code word increases faster than t*log₂(n). A double error correcting (DEC) code that can correct two bits in a 32-bit word needs more than 10 check bits; a DEC that can correct two bits in a 64-bit word needs at least 12 check bits. This added check bit overhead is carried on all data words whether they have manufacturing faults, or not.

An advantage of error correcting codes that can correct two or more bits is that they can correct non-classical faults. But the complexity of the computation is a limiting factor of such codes. All block-oriented codes with t>1 use primitive polynomials operating on a finite field, which has the effect of limiting the size of n. In contrast, because the SEC/DED Hamming code is one of an extremely small set of perfect codes and is simple, the SEC/DED Hamming code can be easily implemented. In fact, the two operations of Hamming codes (check bit generation and error correction) those two operations use the same logical structure. Further, the SEC/DED Hamming code is compact, so its use does not cause issues with data read or write latency.

Embodiments of the inventive concept can extend to the following statements, without limitation:

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage, the correction vector circuitry including correction vector generation circuitry to generate a correction vector from the fault information and an XOR gate to generate the alternate data vector by XORing the data vector with the correction vector; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage, the correction vector circuitry including correction vector generation circuitry to generate a correction vector from the fault information and an XOR gate to generate the alternate data vector by XORing the data vector with the correction vector, the correction vector including a 1 bit corresponding to each data bit the fault information indicates is stuck and a 0 bit for all other bits; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the first error correcting circuitry is identical to the second error correcting circuitry.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the first storage and the second storage are the same storage.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the final data vector circuitry is capable of detecting and correcting a single soft bit error, a single stuck-at bit error, and both a single soft bit error and a single stuck-at bit error, and the final data vector circuitry is capable of detecting a multi bit error.

An embodiment of the inventive concept includes a memory module, comprising: first storage for a data vector; second storage for a check vector; first error correcting circuitry to identify and correct any first bits in the data vector that are in error, wherein the first error correcting circuitry is capable of identifying whether there are no bit errors, a single bit error, or a multi bit error in the data vector; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error, wherein the second error correcting circuitry is capable of identifying whether there are no bit errors, a single bit error, or a multi bit error in the alternate data vector; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the final data vector circuitry is operative to: if the fault information indicates that there are no bits that are stuck, use the first error correcting circuitry with the data vector and the check bits to produce the final data vector; if the second error correcting circuitry indicates a multi bit error, use the second error correcting circuitry with the alternate data vector and the check bits to produce the final data vector; if the first error correcting circuitry indicates fewer errors than the second error correcting circuitry, use the first error correcting circuitry with the data vector and the check bits to produce the final data vector; and if the second error correcting circuitry indicates fewer errors than the first error correcting circuitry, use the second error correcting circuitry with the alternate data vector and the check bits to produce the final data vector.

An embodiment of the inventive concept includes a memory module, comprising: first storage for a data vector; second storage for a check vector; first error correcting circuitry to identify and correct any first bits in the data vector that are in error, wherein the first error correcting circuitry implements a single error correcting/double error detecting (SEC/DED) Hamming code; fault information storage identifying one or more bits in the first storage that are stuck; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a memory module, comprising: first storage for a data vector; second storage for a check vector; first error correcting circuitry to identify and correct any first bits in the data vector that are in error; fault information storage identifying one or more bits in the first storage that are stuck; correction vector circuitry to generate an alternate data vector using the fault information storage; second error correcting circuitry to identify and correct any second bits in the alternate data vector that are in error, wherein the second error correcting circuitry implements a single error correcting/double error detecting (SEC/DED) Hamming code; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage, the correction vector circuitry including correction vector generation circuitry to generate a correction vector from the fault information and an XOR gate to generate the alternate data vector by XORing the data vector with the correction vector; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage, the correction vector circuitry including correction vector generation circuitry to generate a correction vector from the fault information and an XOR gate to generate the alternate data vector by XORing the data vector with the correction vector, the correction vector including a 1 bit corresponding to each data bit the fault information indicates is stuck and a 0 bit for all other bits; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the first error correcting circuitry is identical to the second error correcting circuitry.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the first storage and the second storage are the same storage.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the final data vector circuitry is capable of detecting and correcting a single soft bit error, a single stuck-at bit error, and both a single soft bit error and a single stuck-at bit error, and the final data vector circuitry is capable of detecting a multi bit error.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error, wherein the first error correcting circuitry is capable of identifying whether there are no bit errors, a single bit error, or a multi bit error in the data vector; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error, wherein the second error correcting circuitry is capable of identifying whether there are no bit errors, a single bit error, or a multi bit error in the alternate data vector; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits, wherein the final data vector circuitry is operative to: if the fault information indicates that there are no bits that are stuck, use the first error correcting circuitry with the data vector and the check bits to produce the final data vector; if the second error correcting circuitry indicates a multi bit error, use the second error correcting circuitry with the alternate data vector and the check bits to produce the final data vector; if the first error correcting circuitry indicates fewer errors than the second error correcting circuitry, use the first error correcting circuitry with the data vector and the check bits to produce the final data vector; and if the second error correcting circuitry indicates fewer errors than the first error correcting circuitry, use the second error correcting circuitry with the alternate data vector and the check bits to produce the final data vector.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error, wherein the first error correcting circuitry implements a single error correcting/double error detecting (SEC/DED) Hamming code; correction vector circuitry to generate an alternate data vector using the fault information storage; second error correcting circuitry to identify and correct any second bits in the alternate data vector that are in error; and final data vector circuitry to generate a final data vector from the data vector, the alternate data vector, the first bits, and the second bits.

An embodiment of the inventive concept includes a system, comprising: a computer; a memory module in the computer, the memory including: first storage for a data vector; second storage for a check vector; and fault information storage identifying one or more bits in the first storage that are stuck; first error correcting circuitry to identify and correct any first bits in the data vector that are in error; correction vector circuitry to generate an alternate data vector using the fault information storage; second error correcting circuitry to identify and correct any second bits in the alternate data vector that are in error, wherein the second error correcting circuitry implements a single error correcting/double error detecting (SEC/DED) Hamming code; and final data vector circuitry to generate a final data vector from the data vector, the alternate data vector, the first bits, and the second bits.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector, wherein the method is capable of detecting and correcting a single soft bit error, a single stuck-at bit error, and both a single soft bit error and a single stuck-at bit error, and the method is capable of detecting a multi bit error.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector, wherein the first storage and the second storage are the same storage.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector, wherein the first error correcting circuitry is identical to the second error correcting circuitry.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information including generating the correction vector to include a 1 bit for each bit that the fault information indicates is stuck, and a 0 bit for all other bits; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector.

An embodiment of the inventive concept includes a method, comprising: reading a data vector from a first storage; reading a check vector from a second storage; identifying, using first error correcting circuitry, any first bits in the data vector that are in error based on the check vector including identifying whether there are no bit errors, a single bit error, or a multi bit error in the data vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector including identifying whether there are no bit errors, a single bit error, or a multi bit error in the alternate data vector; using the data vector, the alternate data vector, the first bits, and the second bits to generate a final data vector; and outputting the final data vector.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector, wherein using the data vector, the alternate data vector, the first bits, and the second bits to generate a final data vector includes: if the fault information indicates that there are no bits that are stuck, using the first the data vector to produce the final data vector; if the second error correcting circuitry indicates a multi bit error, using the second error correcting circuitry with the alternate data vector and the check bits to produce the final data vector; if the first error correcting circuitry indicates fewer errors than the second error correcting circuitry, using the first error correcting circuitry with the data vector and the check bits to produce the final data vector; and if the second error correcting circuitry indicates fewer errors than the first error correcting circuitry, using the second error correcting circuitry with the alternate data vector and the check bits to produce the final data vector.

An embodiment of the inventive concept includes a method, comprising: reading a data vector from a first storage; reading a check vector from a second storage; identifying, using first error correcting circuitry, any first bits in the data vector that are in error based on the check vector, the first error correcting circuitry implementing a single error correcting/double error detecting (SEC/DED) Hamming code; reading fault information for the first storage; generating a correction vector from the fault information; XORing the correction vector with the data vector to generate an alternate data vector; identifying, using second error correcting circuitry, any second bits in the alternate data vector that are in error based on the check vector; using the data vector, the alternate data vector, the first bits, and the second bits to generate a final data vector; and outputting the final data vector.

An embodiment of the inventive concept includes a method, comprising: reading a data vector from a first storage; reading a check vector from a second storage; identifying, using first error correcting circuitry, any first bits in the data vector that are in error based on the check vector; reading fault information for the first storage; generating a correction vector from the fault information; XORing the correction vector with the data vector to generate an alternate data vector; identifying, using second error correcting circuitry, any second bits in the alternate data vector that are in error based on the check vector, the second error correcting circuitry implementing a single error correcting/double error detecting (SEC/DED) Hamming code; using the data vector, the alternate data vector, the first bits, and the second bits to generate a final data vector; and outputting the final data vector.

The following discussion is intended to provide a brief, general description of a suitable machine or machines in which certain aspects of the inventive concept can be implemented. Typically, the machine or machines include a system bus to which is attached processors, memory, e.g., random access memory (RAM), read-only memory (ROM), or other state preserving medium, storage devices, a video interface, and input/output interface ports. The machine or machines can be controlled, at least in part, by input from conventional input devices, such as keyboards, mice, etc., as well as by directives received from another machine, interaction with a virtual reality (VR) environment, biometric feedback, or other input signal. As used herein, the term “machine” is intended to broadly encompass a single machine, a virtual machine, or a system of communicatively coupled machines, virtual machines, or devices operating together. Exemplary machines include computing devices such as personal computers, workstations, servers, portable computers, handheld devices, telephones, tablets, etc., as well as transportation devices, such as private or public transportation, e.g., automobiles, trains, cabs, etc.

The machine or machines can include embedded controllers, such as programmable or non-programmable logic devices or arrays, Application Specific Integrated Circuits (ASICs), embedded computers, smart cards, and the like. The machine or machines can utilize one or more connections to one or more remote machines, such as through a network interface, modem, or other communicative coupling. Machines can be interconnected by way of a physical and/or logical network, such as an intranet, the Internet, local area networks, wide area networks, etc. One skilled in the art will appreciate that network communication can utilize various wired and/or wireless short range or long range carriers and protocols, including radio frequency (RF), satellite, microwave, Institute of Electrical and Electronics Engineers (IEEE) 802.11, Bluetooth®, optical, infrared, cable, laser, etc.

Embodiments of the present inventive concept can be described by reference to or in conjunction with associated data including functions, procedures, data structures, application programs, etc. which when accessed by a machine results in the machine performing tasks or defining abstract data types or low-level hardware contexts. Associated data can be stored in, for example, the volatile and/or non-volatile memory, e.g., RAM, ROM, etc., or in other storage devices and their associated storage media, including hard-drives, floppy-disks, optical storage, tapes, flash memory, memory sticks, digital video disks, biological storage, etc. Associated data can be delivered over transmission environments, including the physical and/or logical network, in the form of packets, serial data, parallel data, propagated signals, etc., and can be used in a compressed or encrypted format. Associated data can be used in a distributed environment, and stored locally and/or remotely for machine access.

Embodiments of the inventive concept can include a tangible, non-transitory machine-readable medium comprising instructions executable by one or more processors, the instructions comprising instructions to perform the elements of the inventive concepts as described herein.

Having described and illustrated the principles of the inventive concept with reference to illustrated embodiments, it will be recognized that the illustrated embodiments can be modified in arrangement and detail without departing from such principles, and can be combined in any desired manner. And, although the foregoing discussion has focused on particular embodiments, other configurations are contemplated. In particular, even though expressions such as “according to an embodiment of the inventive concept” or the like are used herein, these phrases are meant to generally reference embodiment possibilities, and are not intended to limit the inventive concept to particular embodiment configurations. As used herein, these terms can reference the same or different embodiments that are combinable into other embodiments.

The foregoing illustrative embodiments are not to be construed as limiting the inventive concept thereof. Although a few embodiments have been described, those skilled in the art will readily appreciate that many modifications are possible to those embodiments without materially departing from the novel teachings and advantages of the present disclosure. Accordingly, all such modifications are intended to be included within the scope of this inventive concept as defined in the claims.

Consequently, in view of the wide variety of permutations to the embodiments described herein, this detailed description and accompanying material is intended to be illustrative only, and should not be taken as limiting the scope of the inventive concept. What is claimed as the inventive concept, therefore, is all such modifications as may come within the scope and spirit of the following claims and equivalents thereto.

What is claimed is:

1. A memory module (105), comprising:
first storage (115) for a data vector (405);
second storage (120) for a check vector;
first error correcting circuitry (125) to identify and correct any first bits in the data vector (405) that are in error;
fault information storage (130) identifying one or more bits in the first storage (115) that are stuck;
correction vector circuitry (135) to generate an alternate data vector (410) using the fault information storage (130);
second error correcting circuitry (140) to identify and correct any second bits in the alternate data vector (410) that are in error; and
final data vector circuitry (145) to generate a final data vector (405) from the data vector (405), the alternate data vector (410), the first bits, and the second bits.

2. A memory module (105) according to claim 1, wherein the correction vector circuitry (135) includes:
correction vector (315) generation circuitry (205) to generate a correction vector (315) from the fault information; and
an XOR gate (210) to generate the alternate data vector (410) by XORing the data vector (405) with the correction vector (315).

3. A memory module (105) according to claim 2, wherein the correction vector (315) includes a 1 bit corresponding to each data bit the fault information indicates is stuck and a 0 bit for all other bits.

4. A memory module (105) according to claim 1, wherein:
the final data vector circuitry (145) is capable of detecting and correcting a single soft bit error, a single stuck-at bit error, and both a single soft bit error and a single stuck-at bit error; and
the final data vector circuitry (145) is capable of detecting a multi bit error.

5. A memory module (105) according to claim 1, wherein the final data vector circuitry (145) is operative to:
if the fault information indicates that there are no bits that are stuck, use the first error correcting circuitry (125) with the data vector (405) and the check bits to produce the final data vector (405);
if the second error correcting circuitry (140) indicates a multi bit error, use the second error correcting circuitry (140) with the alternate data vector (410) and the check bits to produce the final data vector (405);
if the first error correcting circuitry (125) indicates fewer errors than the second error correcting circuitry (140), use the first error correcting circuitry (125) with the data vector (405) and the check bits to produce the final data vector (405); and
if the second error correcting circuitry (140) indicates fewer errors than the first error correcting circuitry (125), use the second error correcting circuitry (140) with the alternate data vector (410) and the check bits to produce the final data vector (405).

6. A memory module (105) according to claim 1, wherein the first error correcting circuitry (125) implements a single error correcting/double error detecting (SEC/DED) Hamming code.

7. A memory module (105) according to claim 1, wherein the second error correcting circuitry (140) implements a single error correcting/double error detecting (SEC/DED) Hamming code.

8. A system, comprising:
a computer (605);
a memory module (105) in the computer (605), the memory including:
first storage (115) for a data vector (405);
second storage (120) for a check vector; and
fault information storage (130) identifying one or more bits in the first storage (115) that are stuck;
first error correcting circuitry (125) to identify and correct any first bits in the data vector (405) that are in error;
correction vector circuitry (135) to generate an alternate data vector (410) using the fault information storage (130);
second error correcting circuitry (140) to identify and correct any second bits in the alternate data vector (410) that are in error; and
final data vector circuitry (145) to generate a final data vector (405) from the data vector (405), the alternate data vector (410), the first bits, and the second bits.

9. A system according to claim 8, wherein the correction vector circuitry (135) includes:
correction vector (315) generation circuitry (205) to generate a correction vector (315) from the fault information; and
an XOR gate (210) to generate the alternate data vector (410) by XORing the data vector (405) with the correction vector (315).

10. A system according to claim 9, wherein the correction vector (315) includes a 1 bit corresponding to each data bit the fault information indicates is stuck and a 0 bit for all other bits.

11. A system according to claim 8, wherein:
the final data vector circuitry (145) is capable of detecting and correcting a single soft bit error, a single stuck-at bit error, and both a single soft bit error and a single stuck-at bit error; and
the final data vector circuitry (145) is capable of detecting a multi bit error.

12. A system according to claim 8, wherein the final data vector circuitry (145) is operative to:
if the fault information indicates that there are no bits that are stuck, use the first error correcting circuitry (125) with the data vector (405) and the check bits to produce the final data vector (405);
if the second error correcting circuitry (140) indicates a multi bit error, use the second error correcting circuitry (140) with the alternate data vector (410) and the check bits to produce the final data vector (405);
if the first error correcting circuitry (125) indicates fewer errors than the second error correcting circuitry (140), use the first error correcting circuitry (125) with the data vector (405) and the check bits to produce the final data vector (405); and
if the second error correcting circuitry (140) indicates fewer errors than the first error correcting circuitry (125), use the second error correcting circuitry (140) with the alternate data vector (410) and the check bits to produce the final data vector (405).

13. A system according to claim 8, wherein the first error correcting circuitry (125) implements a single error correcting/double error detecting (SEC/DED) Hamming code.

14. A system according to claim 8, wherein the second error correcting circuitry (140) implements a single error correcting/double error detecting (SEC/DED) Hamming code.

15. A method, comprising:
reading (705) a data vector (405) from a first storage (115);
reading (710) a check vector from a second storage (120);
identifying (715), using first error correcting circuitry (125), any first bits in the data vector (405) that are in error based on the check vector;
reading (720) fault information for the first storage (115);
generating (725) a correction vector (315) from the fault information;
XORing (730) the correction vector (315) with the data vector (405) to generate an alternate data vector (410);
identifying (735), using second error correcting circuitry (140), any second bits in the alternate data vector (410) that are in error based on the check vector;
using (740) the data vector (405), the alternate data vector (410), the first bits, and the second bits to generate a final data vector (405); and
outputting (745) the final data vector (405).

16. A method according to claim 15, wherein:
the method is capable of detecting and correcting a single soft bit error, a single stuck-at bit error, and both a single soft bit error and a single stuck-at bit error; and
the method is capable of detecting a multi bit error.

17. A method according to claim 15, wherein generating (725) a correction vector (315) from the fault information includes generating (725) the correction vector (315) to include a 1 bit for each bit that the fault information indicates is stuck, and a 0 bit for all other bits.

18. A method according to claim 15, wherein using (740) the data vector (405), the alternate data vector (410), the first bits, and the second bits to generate a final data vector (405) includes:
if the fault information indicates that there are no bits that are stuck, using (805) the first the data vector (405) to produce the final data vector (405);
if the second error correcting circuitry (140) indicates a multi bit error, using (820) the second error correcting circuitry (140) with the alternate data vector (410) and the check bits to produce the final data vector (405);
if the first error correcting circuitry (125) indicates fewer errors than the second error correcting circuitry (140), using (820) the first error correcting circuitry (125) with the data vector (405) and the check bits to produce the final data vector (405); and
if the second error correcting circuitry (140) indicates fewer errors than the first error correcting circuitry (125), using (820) the second error correcting circuitry (140) with the alternate data vector (410) and the check bits to produce the final data vector (405).

19. A method according to claim 15, wherein the first error correcting circuitry (125) implements a single error correcting/double error detecting (SEC/DED) Hamming code.

20. A method according to claim 15, wherein the second error correcting circuitry (140) implements a single error correcting/double error detecting (SEC/DED) Hamming code.
